(19) United States
(12) Patent Application Publication
(10) Pub. No.: US 2013/0118792 A1
(43) Pub. Date: May 16, 2013

(54) PRINTED CIRCUIT BOARD AND METHOD FOR MANUFACTURING THE SAME

(71) Applicant: SAMSUNG ELECTRO-MECHANICS CO., LTD., Suwon (KR)

(72) Inventor: Byung Seung MIN, Busan (KR)

(73) Assignee: SAMSUNG ELECTRO-MECHANICS CO., LTD., Suwon (KR)

(21) Appl. No.: 13/672,063

(22) Filed: Nov. 8, 2012

(30) Foreign Application Priority Data
Nov. 10, 2011 (KR) 10-2011-0117020

(51) Int. Cl. H05K 1/02; H05K 3/10

(52) U.S. Cl. CPC H05K 1/02; H05K 3/10; H05K 3/107
USPC 174/262; 427/97.2; 205/125

(57) ABSTRACT

Disclosed herein is a method for manufacturing a printed circuit board, including: applying a solder resist to an insulating material; forming a cavity in the insulating material and the solder resist; forming a seed layer on a surface of the insulating material including the inside of the cavity; forming circuit patterns by plating the inside of the cavity; removing the seed layer formed on the surface of the solder resist; reapplying the solder resist on the solder resist from which the seed layer is removed; and opening a bump forming region of the reapplied solder resist, whereby micro circuits can be easily implemented.

### CROSS REFERENCE(S) TO RELATED APPLICATIONS

This application claims the benefit under 35 U.S.C. Section 119 of Korean Patent Application Serial No. 10-2011-0117020, entitled “Printed Circuit Board and Method for Manufacturing the Same” filed on Nov. 10, 2011, which is hereby incorporated by reference in its entirety into this application.

### BACKGROUND OF THE INVENTION

1. Technical Field

The present invention relates to a printed circuit board, and more particularly, to a printed circuit board and a method for manufacturing the same capable of implementing micro circuits.

2. Description of the Related Art

In recent years, technologies for small and highly integrated electronic devices and products have been seamlessly developed due to the advance of electronic devices and products. Therefore, a process of manufacturing a printed circuit board used for electronic devices, products, or the like, has been diversely changed in line with the miniaturization and the technology integration.

The technologies for the method for manufacturing a printed circuit board have been developed from a single printed circuit board at the early stage to multilayer printed circuit board via a double side printed circuit board. In particular, upon manufacturing the multilayer printed circuit board, a method for manufacturing a printed circuit board called a build-up method has been recently developed.

Meanwhile, in order to electrically connect among circuit patterns of each layer and electronic devices, a process of forming various via holes such as an inner via hole (IVH), a blind via hole (BVH), or a plated through hole (PTH), or the like, are required. In the related art, after an insulating material is formed with via holes, when vias are formed by performing chemical plating and electroplating and vias for interlayer electrical connection are formed, the printed circuit board is manufactured by forming the circuit patterns including pads on a surface of the insulating material using a dry film.

However, in order to satisfy a demand for high integration and thinness of the substrate, there is a need to implement the inter-layer high-density connection and a micro circuit. When the printed circuit board is manufactured according to the related art, there is a limitation in implementing the micro circuit. That is, when manufacturing the printed circuit board according to the related art, defects of the printed circuit board may easily occur due to a lift phenomenon of the dry film. The circuit patterns are damaged due to the process of removing the chemical plating or the plating partially remains, such that the defects of the printed circuit board may occur.

### SUMMARY OF THE INVENTION

An object of the present invention is to provide a method for manufacturing a printed circuit board capable of easily implementing micro circuits by using a solder resist for forming circuit patterns, instead of using a dry film used for forming circuit patterns in the related art.

Another object of the present invention is to provide a printed circuit board capable of easily implementing micro circuits by smoothing a surface on which circuit patterns contact a solder resist while adopting a structure in which the circuit patterns are buried in the solder resist.

According to an exemplary embodiment of the present invention, there is provided a method for manufacturing a printed circuit board, including: applying a solder resist to an insulating material; forming a cavity in the insulating material and the solder resist; forming a seed layer on a surface of the insulating material including the inside of the cavity; forming circuit patterns by plating the inside of the cavity; removing the seed layer formed on the surface of the solder resist; reapplying the solder resist on the solder resist from which the seed layer is removed; opening a bump forming region of the reapplied solder resist.

The cavity formed in the solder resist may form a step by being more expanded than the cavity formed in the insulating material.

The forming of the cavity may include: forming the cavity by processing the insulating material and the solder resist; and selectively exposing, developing, and delaminating the solder resist so that the cavity forms a step.

The opening of the bump forming region of the reapplied solder resist may include opening the bump forming region by selectively exposing, developing, and delaminating the reapplied solder resist.

The circuit pattern may include: a via formed by plating the inside of the insulating material; and a pad electrically connected with the via and formed by plating the inside of the solder resist.

The surface on which the side of the pad contacts the solder resist may be smoothly formed.

The roughness of the surface on which the side of the pad contacts the solder resist may be the same as the roughness on which the insulating material contacts the solder resist.

The pad may have a shape in which an area is reduced toward the bottom from the top.

The cavity may be a hole through which the insulating material and the solder resist pass.

The cavity may be a trench collapsed up to a predetermined depth from one surface of the insulating material by passing through the solder resist.

The forming of the seed layer may be performed by an electroless plating method.

The forming of the circuit pattern may be performed by an electroplating method.

According to another exemplary embodiment of the present invention, there is provided a printed circuit board, including: an insulating material; a via formed in the insulating material; a pad formed on the insulating material and electrically connected with the via; a solder resist applied to the insulating material on which the pad is formed, some region thereof being opened so that a portion of the pad is exposed on a surface thereof, wherein a surface in which the side of the pad contacts the solder resist is smoothly formed.

The roughness of the surface on which the side of the pad contacts the solder resist may be the same as the roughness on which the insulating material contacts the solder resist.

The pad may have a shape in which an area is reduced toward the bottom from the top.

The solder resist may open a bump forming region so that a portion of the pad is exposed on the surface thereof.

The printed circuit board may further include a bump formed in the bump forming region.

### BRIEF DESCRIPTION OF THE DRAWINGS

FIG. 1 is a cross-sectional view of a printed circuit board according to an exemplary embodiment of the present invention.

FIG. 2 is an operating flow chart showing a process of manufacturing a printed circuit board according to the exemplary embodiment of the printed circuit board.

FIGS. 3 to 11 are cross-sectional views showing a process of manufacturing a printed circuit board according to the exemplary embodiment of the present invention.

### DESCRIPTION OF THE PREFERRED EMBODIMENTS

Terms and words used in the present specification and claims are not to be construed as a general or dictionary meaning but are to be construed meaning and concepts meeting the technical ideas of the present invention based on a principle that the inventors can appropriately define the concepts of terms in order to describe their own inventions in the best mode.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

Hereinafter, exemplary embodiments of the present invention will be described in detail with reference to the accompanying drawings.

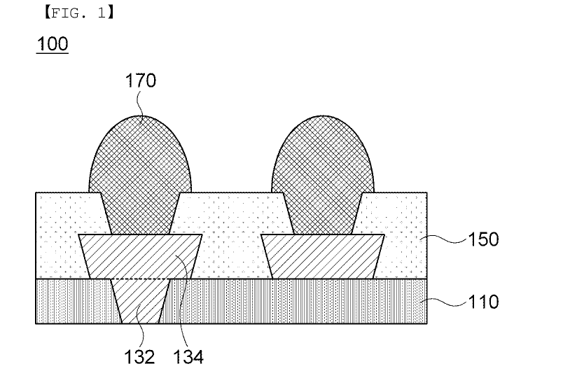

FIG. 1 is a cross-sectional view of a printed circuit board according to an exemplary embodiment of the present invention.

As shown in FIG. 1, a printed circuit board 100 is configured to include an insulating material 110, a circuit pattern 130, a solder resist 150, and a bump 170.

The insulating material 110, which is a member supporting the printed circuit board 100, may be composed of a material having small electric conductivity and barely passes through current, such as prepreg, polyimide, polyethyeleneterepthalate (PET), cyanide ester, ajinomoto build up film (ABF), epoxy, or the like, but is not limited thereto. Therefore, the insulating material may be composed of various materials.

Meanwhile, the configuration of the printed circuit board as shown in FIG. 1 is shown by way of example only. Therefore, the printed circuit board may be a single printed circuit board, a double side printed circuit board, and a multilayer printed circuit board. The technical characteristics of the present invention may be applied similar thereto.

The circuit pattern 130 is configured to a via 132 formed in the insulating layer 110 and a pad 134 and a pad formed on the insulating material 110 and electrically connected with a via 132. In this case, a side of the pad 134 has an inclined structure. In more detail, the pad 134 may have a shape in which an area is reduced toward the bottom from the top.

Further, the circuit pattern 130 may be made of copper (Cu), silver (Ag), gold (Au), aluminum (Al), iron (Fe), titanium (Ti), tin (Sn), nickel (Ni), molybdenum (Mo), or the like. In order to form the circuit pattern 130, an electroless plating method and an electroplating method may be used.

Here, the electroless plating method is called as chemical plating or autocatalytic plating, which means a method for precipitating metals on the surface of the objected to be treated by autocatalytically reducing metal ions in a metal salt aqueous solution by a force of a reducing agent without being supplied with electric energy from the outside. The electroless plating method is generally performed by a pre-treatment process for performing the electroplating so as to smoothly perform the electroplating and may be applied to various substrates made of a material such as plastic, organic matter, or the like.

In addition, the electroplating method means a method for thinly coating other metals on the surface of the metal by using an electrolysis principle.

In addition, the circuit pattern 130 may be formed by using various methods such as chemical vapor deposition (CVD) or physical vapor deposition (PVD), or the like.

The solder resist 150 is applied to the insulating material 110 on which the pad 134 is formed and some region thereof may be opened so that a part of the pad 134 is exposed thereof.

Describing in more detail, the pad 134 is formed in a structure in which the pad 134 is buried in the solder resist 150 and may be open the bump forming region A of the solder resist 150 so that the a portion of the top surface of the pad 134 is exposed thereof.

To this end, after the solder resist 150 is applied on the insulating material 110 on which the circuit pattern 130 is formed, the bump forming region A may be opened by selectively exposing, developing, and laminating the solder resist 150.

In this case, the solder resist 150, which is one of the insulating permanent coating material, may be made of a coating layer covering the circuit pattern 130 so as not to cause the undesired connection due to the soldering performed when mounting the electronic devices.

In addition, since the solder resist 150 shields the pad coating the circuit pattern 130 and required for the soldering of the electronic device, the remaining portion except for the periphery of the portion at which the electronic devices are mounted, the solder resist 150 is called the solder mask and prevents the short, erosion, pollution, or the like, of the printed circuit board and remains as the coating layer on the substrate may serve to protect the circuit from the impact, humidity, chemicals of the outside even after manufacturing the printed circuit board.

The bump 170, which is a member formed in the bump forming region A for mounting the electronic device, may be made of metal materials such as copper (Cu), silver (Ag), gold (Au), aluminum (Al), iron (Fe), titanium (Ti), tin (Sn), nickel (Ni), molybdenum (Mo), or the like.

Meanwhile, the surface on which the side of the pad 134 contacts the solder resist 150 may be smoothly formed. Since the side of the pad 134 is not damaged by the etching similar to the circuit pattern manufactured according to the related art, the micro pattern may be easily implemented.

In other words, in the case of the printed circuit board manufactured according to the related art, both of the top surface and the side surface of the circuit pattern are etched and thus, the circuit pattern is damaged. In the printed circuit board according to the exemplary embodiment of the present invention, since the roughness of the surface on which the side of the pad 134 contacts the solder resist 150 is equal to that of the surface on which the insulating material 110 contacts the solder resist 150, the circuit pattern is not damaged and thus, the micro circuit may be easily implemented.

Hereinafter, a process of manufacturing a printed circuit board according to the exemplary embodiment of the present invention will be described.

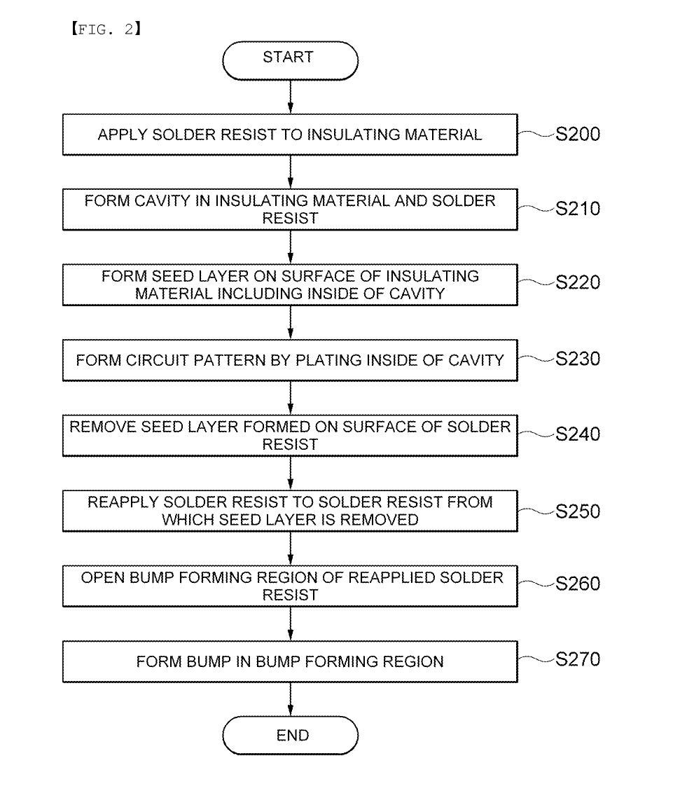

FIG. 2 is an operating flow chart showing a process of manufacturing a printed circuit board according to the exemplary embodiment of the printed circuit board and FIGS. 3 to 11 are cross-sectional views showing a process of manufacturing a printed circuit board according to the exemplary embodiment of the present invention.

As shown in FIGS. 2 and 3, a solder resist 150a is applied to the insulating material 110 (S200). Herein, the insulating material 110, which is a member supporting the printed circuit board 100, may be composed of a material having small electric conductivity and barely passes through current, such as prepreg, polyimide, polyethyeleneterepthalate (PET), cyanide ester, ajinomoto build up film (ABF), epoxy, or the like, but is not limited thereto. Therefore, the insulating material may be composed of various materials.

Meanwhile, the configuration of the printed circuit board as shown in FIG. 1 is shown by way of example only. Therefore, the printed circuit board may be a single printed circuit board, a double side printed circuit board, and a multilayer printed circuit board. The technical characteristics of the present invention may be applied similar thereto.

Next, as shown in FIG. 2, a cavity 140 is formed in the insulating material 110 and the solder resist 150a (S210). Here, the cavity 140a formed in the solder resist 150 may form a step by being expanded than a cavity 140b formed in the insulating material 110.

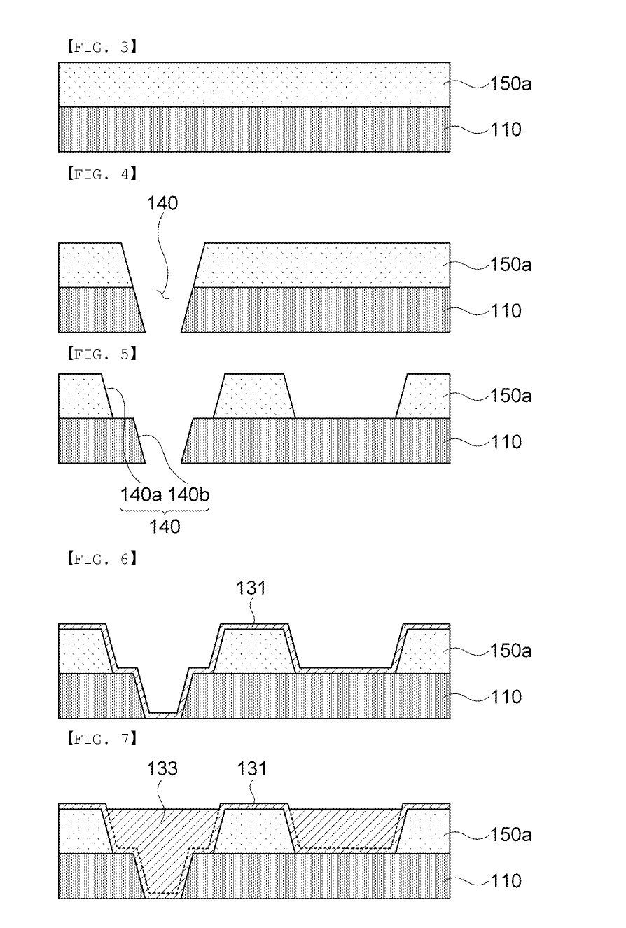

To this end, as shown in FIG. 4, the cavity 140 is formed by processing the insulating material 110 and the solder resist 150a and as shown in FIG. 5, the solder resist 150a may be selectively exposed, developed, and delaminated so that the cavity 140 forms the step.

In addition, the cavity 140 may be formed to have a hole through which the insulating material 110 and the solder resist 150a passes and a trench collapsed to a predetermined depth from one surface of the insulating material 110 passing through the solder resist 150a.

Next, as shown in FIG. 6, a seed layer 131 is formed on the surface of the insulating material 110 including the inside of the cavity 140 (S220). Here, the seed layer 131 may be formed using the electroless plating method 131. The electroless plating method is called as chemical plating or autocatalytic plating, which means a method for precipitating metals on the surface of the objected to be treated by autocatalytically reducing metal ions in a metal salt aqueous solution by a force of a reducing agent without being supplied with electric energy from the outside. The electroless plating method is generally performed by a pre-treatment process for performing the electroplating so as to smoothly perform the electroplating and may be applied to various substrates made of a material such as plastic, organic matter, or the like.

In addition, the seed layer 131 may be formed by using various methods such as chemical vapor deposition (CVD) or physical vapor deposition (PVD), or the like.

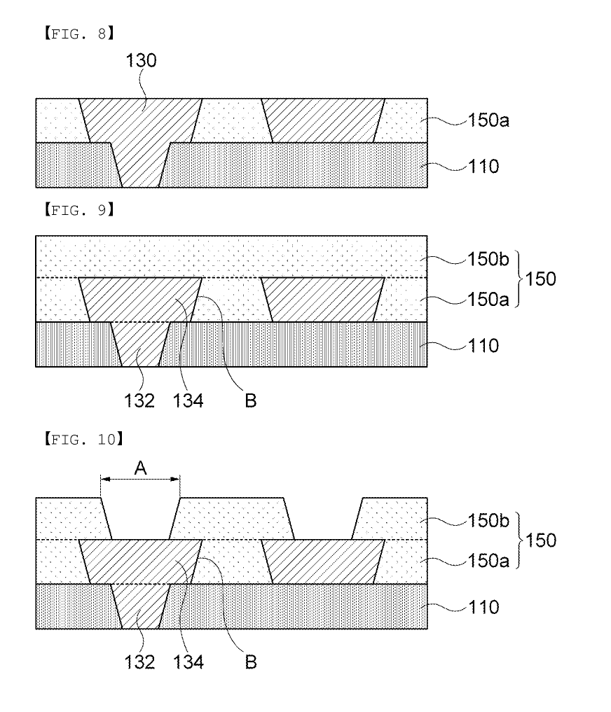

Further, as shown in FIG. 7, the circuit pattern 130 is formed by plating the inside of the cavity 140 (S230). Here, the circuit pattern 130 may be formed by forming the metal layer 133 on the seed layer 131 formed using the electroless plating method by using the electroplating method. The electroplating method means a method for coating a thin layer of other metals on the surface of the metal by using the electrolysis principle.

Next, as shown in FIG. 8, the seed layer 131 on the surface of the solder resist 150a is removed (S240). In this case, the method for removing the seed layer 131 may use a flash etching scheme or a polishing scheme, but is not limited thereto.

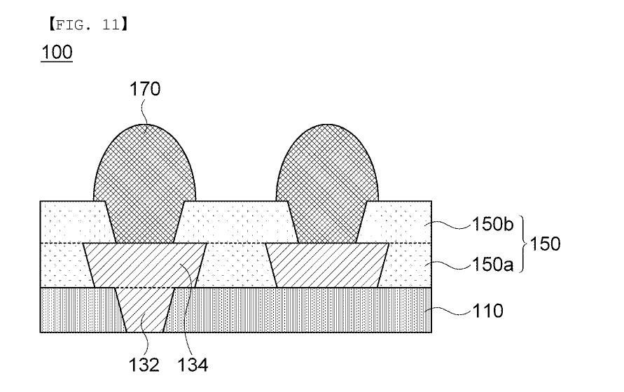

Then, as shown in FIG. 9, the solder resist 150b is reapplied to the solder resist 150a from which the seed layer 131 is removed (S250).

Then, the bump forming region A of the reapplied the solder resistor (150b) is opened (S260). Herein, the opening of the bump forming region A in the solder resist 150b may be implemented by a process of reapplying the solder resist 150b on the solder resist 150a from which the seed layer 131 is removed and then, selectively exposing, developing, and delaminating the solder resist 150b so that the bump forming region A is opened.

Next, as shown in FIG. 11, the bump 170 is formed in the bump forming region A (S270).

In this case, structurally describing the circuit pattern 130, the circuit pattern 130 may be configured to include the via 132 formed by plating the inside of the insulating material 110 and the pad 134 electrically connected with the via 132 and formed by plating the inside of the solder resist 150, wherein the surface on which the side of the pad 134 contacts the solder resist 150a may be smoothly configured. That is, the roughness of the surface on which the side of the pad 134 contacts the solder resist 150a may be formed similar to the surface on which the insulating material 110 contacts the solder resist 150a.

Further, the side of the pad 134 has an inclined structure. In more detail, the pad 134 may have a shape in which an area is reduced toward the bottom from the top.

Describing in conclusion, since the circuit pattern is formed by using the dry film according to the related art, both of the top surface and the side of the circuit pattern are etched when removing the seed layer, thereby damaging the circuit pattern. In the exemplary embodiment of the present invention, since the side of the circuit pattern is previously buried in the solder resist, only the top surface of the circuit pattern is etched when the seed layer is removed. Therefore, the surface on which the side B of the pad 134 contacts the solder resist 150 may be smoothly formed. Since the side of the pad 134 is not damaged by the etching similar to the circuit pattern manufactured according to the related art, the micro circuit may be easily implemented.

In addition, in order to form more easily the micro circuit on the printed circuit substrate, the development of a new material is additionally needed. However, the exemplary embodiment of the present invention may have additional advantages in implementing the micro circuit using the existing material.

As set forth above, the printed circuit board and the method for manufacturing the same according to the exemplary embodiment of the present invention can easily implement the micro circuits by using the solder resist for forming the circuit patterns, instead of using the dry film used for forming the circuit patterns in the related art.

In addition, the exemplary embodiments of the present invention can easily implement the micro circuits by smoothing the surface on which the circuit patterns contact the solder resist while adopting the structure in which the circuit patterns are buried in the solder resist.

In more detail, the exemplary embodiments of the present invention can remove the defects due to the lift phenomenon of the dry film by using the solder resist for forming the circuit patterns instead of using the dry film used in the related art, and prevent the circuit patterns from remaining or being damaged due to the process of removing the chemical plating, and implement the micro circuits without reducing the size of the circuit patterns.

Further, the exemplary embodiments of the present invention do not need to perform the process of exposing, developing, and delaminating the dry film used in the related art to shorten the manufacturing process, thereby saving the manufacturing costs of the printed circuit board.

As a result, the exemplary embodiments of the present invention can secure the overall reliability of the products in which the printed circuit board is provided.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A method for manufacturing a printed circuit board, comprising:
applying a solder resist to an insulating material;
forming a cavity in the insulating material and the solder resist;
forming a seed layer on a surface of the insulating material including the inside of the cavity;
forming circuit patterns by plating the inside of the cavity;
removing the seed layer formed on the surface of the solder resist;
reapplying the solder resist on the solder resist from which the seed layer is removed;
opening a bump forming region of the reapplied solder resist.

2. The method according to claim 1, wherein the cavity formed in the solder resist forms a step by being more expanded than the cavity formed in the insulating material.

3. The method according to claim 1, wherein the forming of the cavity includes:
forming the cavity by processing the insulating material and the solder resist; and
selectively exposing, developing, and delaminating the solder resist so that the cavity forms a step.

4. The method according to claim 1, wherein the opening of the bump forming region of the reapplied solder resist includes opening the bump forming region by selectively exposing, developing, and delaminating the reapplied solder resist.

5. The method according to claim 1, wherein the circuit pattern includes:
a via formed by plating the inside of the insulating material;
a pad electrically connected with the via and formed by plating the inside of the solder resist.

6. The method according to claim 5, wherein the surface on which the side of the pad contacts the solder resist is smoothly formed.

7. The method according to claim 5, wherein the roughness of the surface on which the side of the pad contacts the solder resist is the same as the roughness on which the insulating material contacts the solder resist.

8. The method according to claim 5, wherein the pad has a shape in which an area is reduced toward the bottom from the top.

9. The method according to claim 1, wherein the cavity is a hole through which the insulating material and the solder resist pass.

10. The method according to claim 1, wherein the cavity is a trench collapsed up to a predetermined depth from one surface of the insulating material by passing through the solder resist.

11. The method according to claim 1, wherein the forming of the seed layer is performed by an electroless plating method.

12. The method according to claim 1, wherein the forming of the circuit pattern is performed by an electroplating method.

13. A printed circuit board, comprising:
an insulating material;
a via formed in the insulating material;
a pad formed on the insulating material and electrically connected with the via;
a solder resist applied to the insulating material on which the pad is formed, some region thereof being opened so that a portion of the pad is exposed on a surface thereof,
wherein a surface in which the side of the pad contacts the solder resist is smoothly formed.

14. The printed circuit board according to claim 13, wherein the roughness of the surface on which the side of the pad contacts the solder resist is the same as the roughness on which the insulating material contacts the solder resist.

15. The printed circuit board according to claim 13, wherein the pad has a shape in which an area is reduced toward the bottom from the top.

16. The printed circuit board according to claim 13, wherein the solder resist opens a bump forming region so that a portion of the pad is exposed on the surface thereof.

17. The printed circuit board according to claim 16, further comprising a bump formed in the bump forming region.
